(19) United States
(12) Patent Application Publication
(10) Pub. No.: US 2019/0348477 A1
(43) Pub. Date: Nov. 14, 2019

(54) DISPLAY PANEL AND MANUFACTURING METHOD THEREOF AND DISPLAY DEVICE

(71) Applicant: Wuhan China Star Optoelectronics Semiconductor Display Technology Co., Ltd., Wuhan (CN)

(72) Inventors: Ching-hung Chien, Shenzhen (CN); Hsiang-lun Hsu, Shenzhen (CN)

(21) Appl. No.: 16/114,181

(22) Filed: Aug. 27, 2018

Related U.S. Application Data
(63) Continuation of application No. PCT/CN2018/097406, filed on Jul. 27, 2018.

(30) Foreign Application Priority Data
May 14, 2018 (CN) 201810455728.1

(51) Int. Cl. H01L 27/32; H01L 51/52; H01L 51/56; H01L 51/00

(52) U.S. Cl. CPC H01L 27/3211; H01L 51/524; H01L 51/5215; H01L 51/0097; H01L 51/5234; H01L 51/56

(57) ABSTRACT

This application discloses a display panel and a manufacturing method thereof and a display device. The display panel comprises a first substrate and a second substrate disposed opposite to each other, a first display element is disposed at a side of the first substrate that is close to the second substrate, a second display element is disposed at a side of the second substrate that is close to the first substrate, and both of a light-exiting surface of the first display element and a light-exiting surface of the second display element are towards the second substrate. Sub-pixels of the first display element and sub-pixels of the second display element are disposed in a staggered manner, and regions in the second display element that correspond to the sub-pixels of the first display element are light transmissive regions.

### CROSS-REFERENCE TO RELATED APPLICATIONS

The present application is a continuation-application of International (PCT) Patent Application No. PCT/CN2018/097406, filed on Jul. 27, 2018, which claims foreign priority of Chinese Patent Application No. 201810455728.1, filed on May 14, 2018 in the State Intellectual Property Office of China, the entire contents of which are hereby incorporated by reference.

### FIELD OF THE INVENTION

This application relates to the technical field of displaying, and more particularly, relates to a display panel and a manufacturing method thereof and a display device.

### BACKGROUND OF THE INVENTION

Organic light emitting diodes (OLEDs) have advantages such as a high contrast, a wide color gamut, being self-luminous, and a fast response speed or the like, and OLEDs are used widely especially in the technical field of flexible displaying. In spite of excellent achievements of the OLEDs in the fields of displaying and illumination nowadays, how to improve the ultrahigh resolution by the OLEDs is still a question that needs to be discussed currently.

### SUMMARY OF THE INVENTION

A main technical problem to be solved by this application is to provide a display panel and a manufacturing method thereof and a display device, which can improve the density of sub-pixels in the display panel, thereby increasing the definition of the display panel and improving the resolution of the display panel.

To solve the aforesaid technical problem, another technical solution adopted by this application is to provide a display device which may comprise a display panel, and the display panel may comprise a first substrate and a second substrate disposed opposite to each other, a first display element is disposed at a side of the first substrate that is close to the second substrate, a second display element is disposed at a side of the second substrate that is close to the first substrate, both of a light-exiting surface of the first display element and a light-exiting surface of the second display element are towards the second substrate; wherein the first substrate and the second substrate are two substrates formed by bending an integral flexible substrate into two parts; the first display element may comprise a first display layer, a first encapsulating layer and a first optical film stacked sequentially, the first display layer is close to a side of the first substrate; the second display element may comprise a second display layer, a second encapsulating layer and a second optical film stacked sequentially, the second display layer is close to a side of the second substrate; wherein sub-pixels of the first display element and sub-pixels of the second display element are disposed in a staggered manner, and regions in the second display element that correspond to the sub-pixels of the first display element are light transmissive regions.

To solve the aforesaid technical problem, another technical solution adopted by this application is to provide a display panel which may comprise a first substrate and a second substrate disposed opposite to each other, a first display element is disposed at a side of the first substrate that is close to the second substrate, a second display element is disposed at a side of the second substrate that is close to the first substrate, both of a light-exiting surface of the first display element and a light-exiting surface of the second display element are towards the second substrate; wherein sub-pixels of the first display element and sub-pixels of the second display element are disposed in a staggered manner, and regions in the second display element that correspond to the sub-pixels of the first display element are light transmissive regions.

To solve the aforesaid technical problem, another technical solution adopted by this application is to provide a manufacturing method of a display panel, and the manufacturing method may comprise: providing a flexible substrate; forming a first display element and a second display element respectively at two regions on a same side of the flexible substrate; wherein both of a light-exiting surface of the first display element and a light-exiting surface of the second display element are towards the second substrate; bending the flexible substrate so that the first display element and the second display element are disposed opposite to each other; wherein sub-pixels of the first display element and sub-pixels of the second display element are disposed in a staggered manner, and regions in the second display element that correspond to the sub-pixels of the first display element are light transmissive regions.

As compared to the prior art, this application has the following benefits: the display panel provided by this application may comprise a first substrate and a second substrate disposed opposite to each other, a first display element is disposed at a side of the first substrate that is close to the second substrate, a second display element is disposed at a side of the second substrate that is close to the first substrate, both of a light-exiting surface of the first display element and a light-exiting surface of the second display element are towards the second substrate; wherein sub-pixels of the first display element and sub-pixels of the second display element are disposed in a staggered manner, and regions in the second display element that correspond to the sub-pixels of the first display element are light transmissive regions. In this way, two display elements are stacked, and moreover, the sub-pixels in the two display elements are disposed in a staggered manner so that the density of the sub-pixels in the display panel is doubled, thereby increasing the distinguishability of the display panel and improving the resolution of the display panel.

### BRIEF DESCRIPTION OF THE DRAWINGS

To describe the technical solutions of embodiments of this application more clearly, the attached drawings necessary for description of the embodiments will be introduced briefly hereinbelow. Obviously, these attached drawings only illustrate some of the embodiments of this application, and those of ordinary skill in the art can further obtain other attached drawings according to these attached drawings without making inventive efforts. In the attached drawings:

FIG. 1 is a schematic structural view of a first embodiment of a display panel provided according to this application.

FIG. 2 is a schematic structural view of a second embodiment of the display panel provided according to this application.

FIG. 3 is a schematic structural view of a third embodiment of the display panel provided according to this application.

FIG. 4 is a schematic flowchart diagram of an embodiment of a manufacturing method of a display panel provided according to this application.

FIG. 5a shows a top view of a flexible substrate during manufacturing the display panel according to the application.

FIG. 5b shows a side view of the flexible substrate of FIG. 5a.

FIG. 5c shows a side view after the flexible substrate of FIG. 5a is bent.

FIG. 6 is a schematic structural view of a fourth embodiment of the display panel provided according to this application.

FIG. 7 is a schematic structural view of a fifth embodiment of the display panel provided according to this application.

### DETAILED DESCRIPTION OF THE INVENTION

Technical solutions of embodiments of this application will be described clearly and completely with reference to the attached drawings illustrating the embodiments of this application. It shall be appreciated that, the embodiments described herein are only used for explaining this application instead of limiting this application. It shall be additionally noted that, only portions relevant to this application instead of all the structures are shown in the attached drawings. All other embodiments that can be obtained by those of ordinary skill in the art from the embodiments of this application without making creative efforts shall fall within the scope of this application.

Terms such as “first”, “second” or the like used in this application are used for distinguishing different objects instead of describing a particular order. Moreover, terms “comprising” and “having” as well as any variants thereof are intended to encompass non-exclusive inclusion. For example, a process, method, system, product or apparatus comprising a series of blocks or units are not limited to these blocks or units that have been clearly listed, but may optionally comprise other blocks or units that are not clearly listed or may optionally comprise other blocks or units that are inherent to the process, method, product or apparatus.

Reference to “embodiment” herein means that a particular feature, structure or characteristic described in connection with embodiments may be comprised in at least one embodiment of this application. This word appearing at various positions in this specification does not necessarily refer to the same embodiment, and does not refer to an independent or alternative embodiment that is mutually exclusive with other embodiments. As shall be apparently or implicitly appreciated by those skilled in the art, the embodiments described herein may be combined with other embodiments.

A display panel generally comprises multiple pixels arranged in the form of an array, and each of the pixels may comprise multiple sub-pixels. For example, one pixel may comprise three sub-pixels which are respectively red (R), green (G) and blue (B). In a process of manufacturing an array substrate based on these pixels, a mask needs to be used for etching process. Therefore, the precision of the mask will limit the density of the pixels, and under the limitation of a fine metal mask (FMM), the density of the pixels is hard to change fundamentally so that the definition of the display screen can not be further improved.

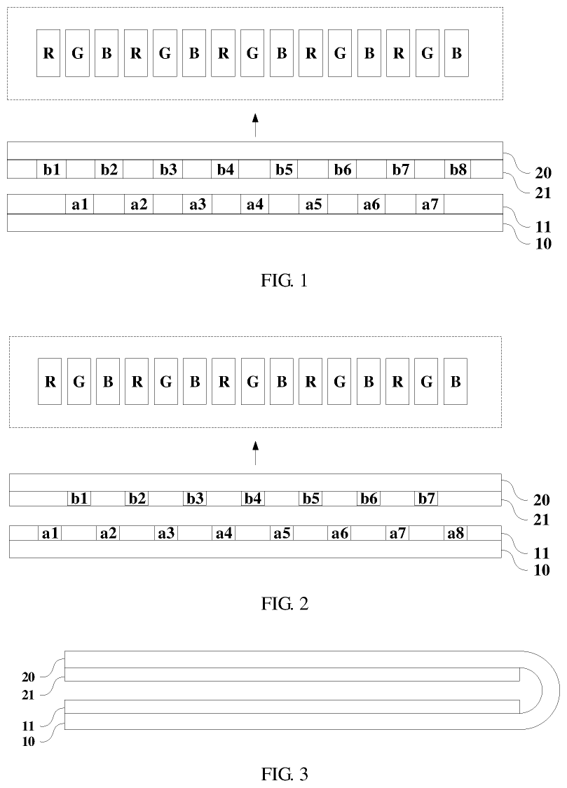

Referring to FIG. 1, FIG. 1 is a schematic structural view of a first embodiment of a display panel provided according to this application. The display panel may comprise a first substrate 10 and a second substrate 20 disposed opposite to each other. A first display element 11 is disposed at a side of the first substrate 10 that is close to the second substrate 20, a second display element 21 is disposed at a side of the second substrate 20 that is close to the first substrate 10, and both of a light-exiting surface of the first display element 11 and a light-exiting surface of the second display element 21 are towards the second substrate 20.

Sub-pixels of the first display element 11 and sub-pixels of the second display element 21 are disposed in a staggered manner.

As shall be appreciated that, in a single display element, the density at which the sub-pixels are arranged is limited. Therefore, in this embodiment, the density of the pixels is improved by stacking two display elements, thereby improving the resolution of the display.

Optionally, in this embodiment, the sub-pixels of the first display element 11 are arranged cyclically in an order of green, red and blue; and the sub-pixels of the second display element 21 are arranged cyclically in an order of red, blue and green.

Specifically, as shown in FIG. 1, in the first display element 11, colors of seven sub-pixels a1 to a7 are respectively: green, red, blue, green, red, blue, green; and in the second display element 21, colors of eight sub-pixels b1 to b8 are respectively: red, blue, green, red, blue, green, red and blue.

The green sub-pixel of the first display element 11 is disposed corresponding to a gap between a red sub-pixel and a blue sub-pixel of the second display element 21 that are adjacent to each other, a red sub-pixel of the first display element 11 is disposed corresponding to a gap between a blue sub-pixel and a green sub-pixel of the second display element 21 that are adjacent to each other, and a blue sub-pixel of the first display element 11 is disposed corresponding to a gap between a green sub-pixel and a red sub-pixel of the second display element 21 that are adjacent to each other.

Specifically, a1 is disposed corresponding to a gap between b1 and b2, a2 is disposed corresponding to a gap between b2 and b3, a3 is disposed corresponding to a gap between b3 and b4, and so on, and this will not be further listed herein. As shown in FIG. 1, in the first display element 11, colors of seven sub-pixels a1 to a3 are respectively: green, red, blue; and in the second display element 21, colors of eight sub-pixels b1 to b4 are respectively: red, blue, green, red.

By the aforesaid arrangement of the sub-pixels, the arrangement of the sub-pixels is stilled presented in an order of red (R), green (G) and blue (B) when viewed from the light-exiting surface of the display panel.

It shall be noted that, although both the light-exiting surface of the first display element 11 and the light-exiting surface of the second display element 21 are towards the second substrate 20, the light emitted by the sub-pixels on the first display element 11 needs to penetrate through the second display element 21 and the second substrate 20, so regions on the second substrate 20 and the second display element 21 that correspond to the sub-pixels of the first display element 11 are light transmissive regions. Specifically, regions between every two sub-pixels in the second display element 21 are light transmissive regions. For example, a region between b1 and b2 is a light transmissive region, and a region between b2 and b3 is a light transmissive region, and so on.

In the aforesaid way, the display panel provided by this embodiment may comprise a first substrate and a second substrate disposed opposite to each other, a first display element is disposed at a side of the first substrate that is close to the second substrate, a second display element is disposed at a side of the second substrate that is close to the first substrate, both of a light-exiting surface of the first display element and a light-exiting surface of the second display element are towards the second substrate; wherein sub-pixels of the first display element and sub-pixels of the second display element are disposed in a staggered manner, and regions in the second display element that correspond to the sub-pixels of the first display element are light transmissive regions. In this way, two display elements are stacked, and moreover, the sub-pixels in the two display elements are disposed in a staggered manner so that the density of the sub-pixels in the display panel is doubled, thereby increasing the definition of the display panel and improving the resolution of the display panel.

Referring to FIG. 2, FIG. 2 is a schematic structural view of a second embodiment of a display panel provided according to this application. The display panel may comprise a first substrate 10 and a second substrate 20 disposed opposite to each other. A first display element 11 is disposed at a side of the first substrate 11 that is close to the second substrate 20, a second display element 21 is disposed at a side of the second substrate 20 that is close to the first substrate 10, and both of a light-exiting surface of the first display element 11 and a light-exiting surface of the second display element 21 are towards the second substrate 20.

Sub-pixels of the first display element 11 and sub-pixels of the second display element 21 are disposed in a staggered manner.

Different from the aforesaid embodiment, in this embodiment, the sub-pixels of the first display element 11 are arranged cyclically in an order of red, blue and green; and the sub-pixels of the second display element 21 are arranged cyclically in an order of green, red and blue.

Specifically, as shown in FIG. 1, in the first display element 11, colors of eight sub-pixels a1 to a8 are respectively: red, blue, green, red, blue, green, red and blue; and in the second display element 21, colors of seven sub-pixels b1 to b7 are respectively: green, red, blue, green, red, blue and green.

A green sub-pixel of the second display element 21 is disposed corresponding to a gap between a red sub-pixel and a blue sub-pixel of the first display element 11 that are adjacent to each other, a red sub-pixel of the second display element 21 is disposed corresponding to a gap between a blue sub-pixel and a green sub-pixel of the first display element 11 that are adjacent to each other, and a blue sub-pixel of the second display element 21 is disposed corresponding to a gap between a green sub-pixel and a red sub-pixel of the first display element 11 that are adjacent to each other.

Specifically, b1 is disposed corresponding to a gap between a1 and a2, b2 is disposed corresponding to a gap between a2 and a3, b3 is disposed corresponding to a gap between a3 and a4, and so on, and this will not be further listed herein.

By the aforesaid arrangement of the sub-pixels, the arrangement of the sub-pixels is stilled presented in an order of red (R), green (G) and blue (B) when viewed from the light-exiting surface of the display panel.

It shall be noted that, although both the light-exiting surface of the first display element 11 and the light-exiting surface of the second display element 21 are towards the second substrate 20, the light emitted by the sub-pixels on the first display element 11 needs to penetrate through the second display element 21 and the second substrate 20, so regions on the second substrate 20 and the second display element 21 that correspond to the sub-pixels of the first display element 11 are light transmissive regions. Specifically, regions between every two sub-pixels in the second display element 21 are light transmissive regions. For example, a region between a1 and a2 is a light transmissive region, and a region between a2 and a3 is a light transmissive region, and so on. Additionally, a region before the first sub-pixel b1 and a region after the last sub-pixel b7 should also be light transmissive regions.

Referring to FIG. 3, FIG. 3 is a schematic structural view of a third embodiment of a display panel provided according to this application. The display panel comprises a first substrate 10 and a second substrate 20 disposed opposite to each other. A first display element 11 is disposed at a side of the first substrate 11 that is close to the second substrate 20, a second display element 21 is disposed at a side of the second substrate 20 that is close to the first substrate 10, and both of a light-exiting surface of the first display element 11 and a light-exiting surface of the second display element 21 are towards the second substrate 20.

Different from the aforesaid embodiments, in this embodiment, the first substrate 10 and the second substrate 20 are two substrates formed by bending an integral flexible substrate into two parts.

This embodiment will be described in detail through a manufacturing process.

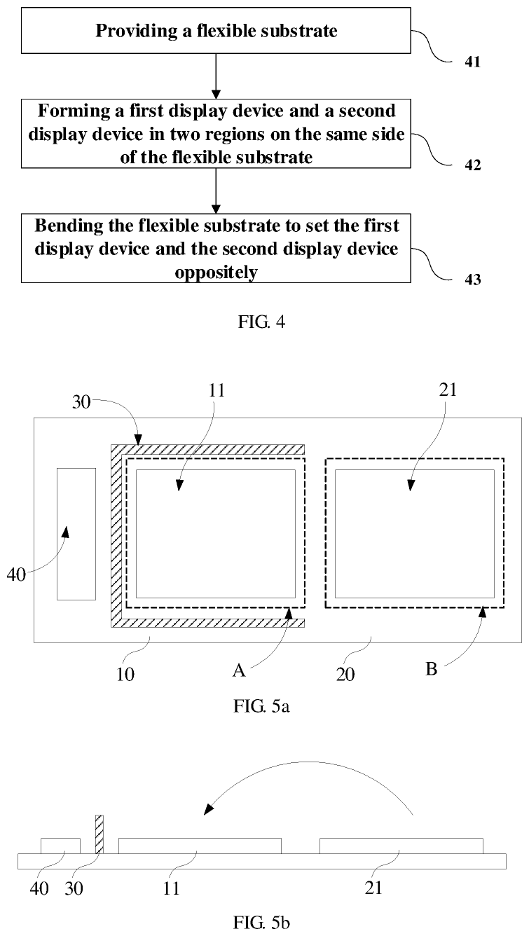

Referring to FIG. 4, FIG. 4 is a schematic flowchart diagram of an embodiment of a manufacturing method of a display panel provided according to this application, and this method comprises:

Block 41: providing a flexible substrate.

Block 42: forming a first display element and a second display element respectively at two regions on a same side of the flexible substrate.

Referring to FIG. 5a, FIG. 5b and FIG. 5c, they are schematic structural view of a block 42 in an embodiment of the manufacturing method of a display panel provided according to this application. The first substrate 10 and the second substrate 20 are an integral flexible substrate. More specifically, FIG. 5a is a top view, FIG. 5b is a side view, and FIG. 5c is a side view after the flexible substrate is bent.

Optionally, a first substrate 10 and a second substrate 20, a region A and a region B, as well as a bending line between the region A and the region B may be pre-defined on the flexible substrate. Then, a first display element 11 and a second display element 22 are formed respectively in the region A and the region B.

Optionally, sealant 30 and a driving circuit 40 may also be formed on the first substrate 10.

The sealant 30 is applied to three side regions outside the first display element 11, and the side close to the bending line is not applied with the sealant, and the driving circuit 40 couples the first display element 11 and the second display element.

Block 43: bending the flexible substrate so that the first display element and the second display element are disposed opposite to each other.

The first substrate 10 and the second substrate 20 may be bonded to form an enclosed space by the sealant 30 applied previously, and the first display element 11 and the second display element 21 are within the enclosed space.

Optionally, the sealant is generally UV adhesive, and after the first substrate 10 and the second substrate 20 are bent, the UV adhesive needs to be irradiated by UV light for curing of the UV adhesive.

Both of a light-exiting surface of the first display element 11 and a light-exiting surface of the second display element 21 are towards the second substrate 20; sub-pixels of the first display element 11 and sub-pixels of the second display element 21 are disposed in a staggered manner, and regions in the second display element 21 that correspond to the sub-pixels of the first display element 11 are light transmissive regions.

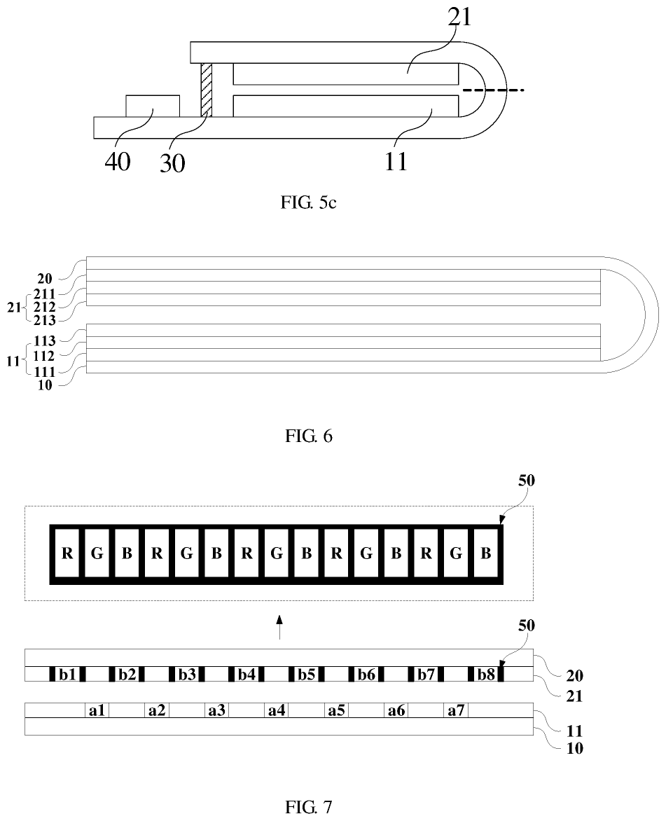

Referring to FIG. 6, FIG. 6 is a schematic structural view of a fourth embodiment of the display panel provided according to this application. The display panel may comprise a first substrate 10 and a second substrate 20 disposed opposite to each other, a first display element 11 is disposed at a side of the first substrate 11 that is close to the second substrate 20, a second display element 21 is disposed at a side of the second substrate 20 that is close to the first substrate 10, and both of a light-exiting surface of the first display element 11 and a light-exiting surface of the second display element 21 are towards the second substrate 20.

Specifically, the first display element 11 may comprise a first display layer 111, a first encapsulating layer 112 and a first optical film 113 stacked sequentially, the first display layer 111 is close to a side of the first substrate 10. The second display element 21 may comprise a second display layer 211, a second encapsulating layer 212 and a second optical film 213 stacked sequentially, and the second display layer 211 is close to a side of the second substrate 20.

It shall be appreciated that, in the manufacturing process, first the display layers are manufactured, then the encapsulating layers are manufactured, and finally the optical films are manufactured for both of the two display elements. Therefore, after the first substrate 10 and the second substrate 20 are bent, the second optical film 213 of the second display element 21 is close to a side of the first substrate 10.

More specifically, the first display layer 111 may comprise a first anode, a first light emitting layer and a first cathode (not shown) stacked sequentially, the first anode is close to a side of the first substrate 10, and the first cathode is a transparent electrode. It shall be appreciated that, in the structural view as shown in FIG. 6, the light-exiting surface of the display panel is an upper surface, so the lower surface of the first display element 11 does not need to emit light and thus the anode of the first display element 11 may adopt a metal electrode (e.g., Mg, Al). The upper surface of the first display element 11 needs to emit light, so the cathode of the first display element 11 may adopt a transparent electrode (e.g., ITO).

More specifically, the second display layer 211 may comprise a second anode, a second light emitting layer and a second cathode (not shown) stacked sequentially, the second anode is close to a side of the second substrate 20, and both the second anode and the second cathode are transparent electrodes. It shall be appreciated that, in the structural view as shown in FIG. 6, the light-exiting surface of the display panel is an upper surface, but the lower surface of the second display element 21 needs to be light transmissive so that the light emitted by the first display element 11 can penetrate it, and thus both the anode and the cathode of the first display element 11 need to adopt transparent electrodes (e.g., ITO).

Referring to FIG. 7, FIG. 7 is a schematic structural view of a fifth embodiment of the display panel provided according to this application. The display panel may comprise a first substrate 10 and a second substrate 20 disposed opposite to each other, a first display element 11 is disposed at a side of the first substrate 11 that is close to the second substrate 20, a second display element 21 is disposed at a side of the second substrate 20 that is close to the first substrate 10, and both of a light-exiting surface of the first display element 11 and a light-exiting surface of the second display element 21 are towards the second substrate 20.

Sub-pixels of the first display element 11 and sub-pixels of the second display element 21 are disposed in a staggered manner, and regions in the second display element 21 that correspond to the sub-pixels of the first display element 11 are light transmissive regions.

Interference between the light emitted by the sub-pixels on the first display element 11 and the light emitted by the sub-pixels on the second display element 21 is likely to occur because the light emitted by the sub-pixels in the first display element 11 penetrates through the light transmissive regions on the second display element 21. In order to prevent the interference between the light respectively emitted by the first display element 11 and the second display element 21, light-blocking regions 50 may be disposed around the sub-pixels of the second display element 21, and a sub-pixel in the first display element 11 is disposed corresponding to a gap between light-blocking regions 50 of two adjacent sub-pixels in the second display element 21.

Specifically, the aforesaid light-blocking regions may be manufactured by adopting a black matrix (BM).

Additionally, this application further provides a display device, and the display device may be specifically an OLED display device, which may be applied to mobile phones, televisions, and other electronic apparatuses capable of displaying. The display device of this embodiment may comprise the display panel provided in each of the aforesaid embodiments, or the display device is manufactured by the manufacturing method of the display panel provided in the aforesaid embodiments. The structures and the manufacture methods of the display device and the display panel are similar, and thus will not be further described herein.

What described above are only the embodiments of the present disclosure, but are not intended to limit the scope of the present disclosure. Any equivalent structures or equivalent process flow modifications that are made according to the specification and the attached drawings of the present disclosure, or any direct or indirect applications of the present disclosure in other related technical fields shall all be covered within the scope of the present disclosure.

What is claimed is:

1. A display device, comprising a display panel, the display panel comprising:
a first substrate;
a second substrate opposite to the first substrate;
a bending portion connecting the first substrate and the second substrate such that the first substrate and the second substrate are substantially parallel to each other and located two opposite two lateral sides of the being portion;
a first display element disposed at a side of the first substrate that is close to the second substrate, the first display element comprising:
a first display layer close to a side of the first substrate and comprising:
a plurality of first sub-pixels; and
a first light-exiting surface which is towards the second substrate, wherein the plurality of first sub-pixels are emitted from the first light-exiting surface;
a first encapsulating layer stacked on the first display layer; and
a first optical film stacked on the first encapsulating layer;
a second display element disposed at a side of the second substrate that is close to the first substrate, wherein a portion of the second display element corresponding to a location of the plurality of first sub-pixels comprise transparent material, and the second display element comprising:
a second display layer close to a side of the first substrate and comprising:
a plurality of second sub-pixels, wherein each of the first sub-pixels and each of the second sub-pixels are alternately arranged; and
a second light-exiting surface which is towards the second substrate, wherein the plurality of second sub-pixels are emitted from the second light-exiting surface;
a second encapsulating layer stacked on the second display layer; and
a second optical film stacked on the second encapsulating layer.

2. The display device of claim 1, wherein
the plurality of first sub-pixels are arranged cyclically in an order of green, red and blue;
the plurality of second sub-pixels are arranged cyclically in an order of red, blue and green;
wherein a green first sub-pixel is disposed corresponding to a gap between a red second sub-pixel and a blue second sub-pixel that are adjacent to each other, a red first sub-pixel is disposed corresponding to a gap between a blue second sub-pixel and a green second sub-pixel that are adjacent to each other, and a first blue sub-pixel is disposed corresponding to a gap between a green second sub-pixel and a red second sub-pixel that are adjacent to each other.

3. The display device of claim 1, wherein
the plurality of first sub-pixels are arranged cyclically in an order of red, blue and green;
the plurality of second sub-pixels are arranged cyclically in an order of green, red and blue;
wherein a green second sub-pixel is disposed corresponding to a gap between a red first sub-pixel and a blue first sub-pixel that are adjacent to each other, a red second sub-pixel is disposed corresponding to a gap between a blue first sub-pixel and a green first sub-pixel that are adjacent to each other, and a blue second sub-pixel is disposed corresponding to a gap between a green first sub-pixel and a red first sub-pixel that are adjacent to each other.

4. The display device of claim 1, wherein
a plurality of light-blocking regions are further disposed around the plurality of second sub-pixels, and the plurality of first sub-pixels are disposed corresponding to a gap between light-blocking regions of two adjacent second sub-pixels.

5. The display device of claim 1, wherein
a sealant is further disposed between the first substrate and the second substrate, and the sealant and the first and second substrates together seal the first display element and the second display element.

6. The display device of claim 1, wherein
the first display layer comprises a first anode, a first light emitting layer and a first cathode stacked sequentially, the first anode is close to a side of the first substrate, and the first cathode is a transparent electrode;
the second display layer comprises a second anode, a second light emitting layer and a second cathode stacked sequentially, the second anode is close to a side of the second substrate, and both the second anode and the second cathode are transparent electrodes.

7. A display panel, comprising:
a first substrate;
a second substrate opposite to the first substrate;
a first display element disposed at a side of the first substrate that is close to the second substrate, the first display element comprising:
a plurality of first sub-pixels; and
a first light-exiting surface which is towards the second substrate, wherein the plurality of first sub-pixels are emitted from the first light-exiting surface;
a second display element disposed at a side of the second substrate that is close to the first substrate, wherein a portion of the second display element corresponding to a location of the plurality of first sub-pixels comprise transparent material, and the second display element comprising:
a plurality of second sub-pixels, wherein each of the first sub-pixels and each of the second sub-pixels are alternately arranged; and
a second light-exiting surface which is towards the second substrate, wherein the plurality of second sub-pixels are emitted from the second light-exiting surface.

8. The display panel of claim 7, wherein
the plurality of first sub-pixels are arranged cyclically in an order of green, red and blue;
the plurality of second sub-pixels are arranged cyclically in an order of red, blue and green;
wherein a green first sub-pixel is disposed corresponding to a gap between a red second sub-pixel and a blue second sub-pixel that are adjacent to each other, a red first sub-pixel is disposed corresponding to a gap between a blue second sub-pixel and a green second sub-pixel that are adjacent to each other, and a blue first sub-pixel is disposed corresponding to a gap between a green second sub-pixel and a red second sub-pixel that are adjacent to each other.

9. The display panel of claim 7, wherein
the plurality of first sub-pixels are arranged cyclically in an order of red, blue and green;
the plurality of second sub-pixels are arranged cyclically in an order of green, red and blue;
wherein a green second sub-pixel is disposed corresponding to a gap between a red first sub-pixel and a blue first sub-pixel that are adjacent to each other, a red second sub-pixel is disposed corresponding to a gap between a blue first sub-pixel and a green first sub-pixel that are adjacent to each other, and a blue second sub-pixel is disposed corresponding to a gap between a green first sub-pixel and a red first sub-pixel that are adjacent to each other.

10. The display panel of claim 7, wherein
a plurality of light-blocking regions are further disposed around the plurality of second sub-pixels, and the plurality of first sub-pixels are disposed corresponding to a gap between light-blocking regions of two adjacent second sub-pixels.

11. The display panel of claim 7, wherein
the first substrate and the second substrate are two substrates formed by bending an integral flexible substrate into two parts.

12. The display panel of claim 11, wherein
a sealant is further disposed between the first substrate and the second substrate, and the sealant and the flexible substrate together seal the first display element and the second display element.

13. The display panel of claim 7, wherein
the first display element comprises:
a first display layer close to a side of the first substrate and comprising:
the plurality of first sub-pixels; and
the first light-exiting surface;
a first encapsulating layer stacked on the first display layer; and
a first optical film stacked on the first encapsulating layer;
the second display element comprises:
a second display layer close to a side of the first substrate and comprising:
the plurality of second sub-pixels; and
the second light-exiting surface;
a second encapsulating layer stacked on the second display layer; and
a second optical film stacked on the second encapsulating layer.

14. The display panel of claim 13, wherein
the first display layer comprises a first anode, a first light emitting layer and a first cathode stacked sequentially, the first anode is close to a side of the first substrate, and the first cathode is a transparent electrode;
the second display layer comprises a second anode, a second light emitting layer and a second cathode stacked sequentially, the second anode is close to a side of the second substrate, and both the second anode and the second cathode are transparent electrodes.

15. A manufacturing method of a display panel, comprising:
providing a first substrate and a second substrate opposite to the first substrate;
forming a first display element disposed at a side of the first substrate that is close to the second substrate, the first display element comprising:
a plurality of first sub-pixels; and
a first light-exiting surface which is towards the second substrate, wherein the plurality of first sub-pixels are emitted from the first light-exiting surface;
forming a second display element disposed at a side of the second substrate that is close to the first substrate, wherein a portion of the second display element corresponding to a location of the plurality of first sub-pixels comprise transparent material, and the second display element comprising:
a plurality of sub-pixels, wherein each of the first sub-pixels and each of the second sub-pixels are alternately arranged; and
a second light-exiting surface which is towards the second substrate, wherein the plurality of second sub-pixels are emitted from the second light-exiting surface.

16. The manufacturing method of claim 15, wherein
the plurality of first sub-pixels are arranged cyclically in an order of green, red and blue;
the plurality of second sub-pixels are arranged cyclically in an order of red, blue and green;
wherein a green first sub-pixel is disposed corresponding to a gap between a red second sub-pixel and a blue second sub-pixel that are adjacent to each other, a red first sub-pixel is disposed corresponding to a gap between a blue second sub-pixel and a green second sub-pixel that are adjacent to each other, and a blue first sub-pixel is disposed corresponding to a gap between a green second sub-pixel and a red second sub-pixel that are adjacent to each other.

17. The manufacturing method of claim 15, wherein
the plurality of first sub-pixels are arranged cyclically in an order of red, blue and green;
the plurality of second sub-pixels are arranged cyclically in an order of green, red and blue;
wherein a green second sub-pixel is disposed corresponding to a gap between a red first sub-pixel and a blue first sub-pixel that are adjacent to each other, a red second sub-pixel is disposed corresponding to a gap between a blue first sub-pixel and a green first sub-pixel that are adjacent to each other, and a blue second sub-pixel is disposed corresponding to a gap between a green first sub-pixel and a red first sub-pixel that are adjacent to each other.

18. The manufacturing method of claim 15, wherein
a plurality of light-blocking regions are further disposed around the plurality of second sub-pixels, and the plurality of first sub-pixels are disposed corresponding to a gap between light-blocking regions of two adjacent second sub-pixels.

19. The manufacturing method of claim 18, wherein
the first substrate and the second substrate formed by bending a flexible substrate, and a bending portion connecting the first substrate and the second substrate such that the first substrate and the second substrate are substantially parallel to each other and located two opposite two lateral sides of the being portion;

20. The manufacturing method of claim 15, wherein
a sealant is further disposed between the first substrate and the second substrate, and the sealant and the first and second substrate together seal the first display element and the second display element.
